(19) United States
(12) Patent Application Publication
(10) Pub. No.: US 2015/0079343 A1
(43) Pub. Date: Mar. 19, 2015

(54) FLUORORESIN SUBSTRATE

(71) Applicant: Sumitomo Electric Fine Polymer, Inc., Sennan-Gun, Osaka (JP)

(72) Inventors: Makoto Nakabayashi, Sennan-gun (JP); Kazuaki Ikeda, Sennan-gun (JP)

(73) Assignee: SUMITOMO ELECTRIC FINE POLYMER, INC., Sennan-Gun, Osaka (JP)

(21) Appl. No.: 14/387,272

(22) PCT Filed: Mar. 25, 2013
(86) PCT No.: PCT/JP2013/058551

§ 371 Date: Sep. 23, 2014

(30) Foreign Application Priority Data
Mar. 26, 2012 (JP) 2012-069591

(51) Int. Cl. H05K 1/02; H05K 1/03

(52) U.S. Cl. CPC H05K 1/0271; H05K 1/0306; H05K 1/024; H05K 2201/015
USPC 428/141; 428/313.9

(57) ABSTRACT

The invention offers a fluororesin substrate that has a dielectric layer being mainly composed of fluororesin and being formed on a metal conductor, that sufficiently suppresses the occurrence of warpage at the time of the reflow, and that enables the exhibiting of sufficiently outstanding high-frequency characteristics, the dielectric layer including hollow glass beads; a fluororesin substrate that has a metal conductor having a surface roughness, Rz, of 2.0 μm or less; a fluororesin substrate that has fluororesin irradiated with an ionizing radiation at an exposure dose of 0.01 to 500 kGy; and a fluororesin substrate that has fluororesin being one or two or more of polytetrafluoroethylene (PTFE), a tetrafluoroethylene-perfluoroalkyl vinyl ether copolymer (PFA), a tetrafluoroethylene-hexafluoropropylene copolymer (FEP), and a tetrafluoroethylene-ethylene copolymer (ETFE).

### TECHNICAL FIELD

The present invention relates to a fluororesin substrate for forming a circuit, the substrate being suitable as a high-frequency circuit substrate to be used in a high-frequency communications device.

### BACKGROUND ART

In response to the recent increase in the amount of information communication, for example, in devices such as an IC card and a mobile telephone, the amount of communication has been increasing in higher-frequency regions such as microwaves and millimeter waves. Consequently, the market has been requiring a high-frequency circuit substrate that can be used in high-frequency regions and that has a smaller transmission delay and transmission loss.

It is desirable that the foregoing high-frequency circuit substrate use a substrate material having a low dielectric constant, ε, and dielectric tangent, tan δ. The types of the above-described material having a low dielectric constant and dielectric tangent include fluororesin such as polytetrafluoroethylene (PTFE). Techniques have been developed to produce a high-frequency circuit substrate (fluororesin substrate) by forming a dielectric layer composed of fluororesin on a metal substrate (metal conductor) formed of copper (Cu) foil or the like (for example, Patent Literatures 1 and 2).

### CITATION LIST

### Patent Literature

Patent Literature 1: The published Japanese patent application Tokukai 2001-7466

Patent Literature 2: The published Japanese patent 4296250

### SUMMARY OF INVENTION

### Technical Problem

Despite the above description, because the fluororesin forming the dielectric layer has a coefficient of thermal expansion (on the order of 10⁻⁵/K) higher than that of Cu (on the order of 10⁻⁶/K) forming the metal conductor, when a fluororesin substrate is produced simply by laminating the fluororesin and the metal conductor, warpage will occur in a reflow process performed at a temperature of 260° C. or so. Once such warpage occurs, the fluororesin substrate cannot be used as a high-frequency circuit substrate.

To solve the foregoing problem, as shown in FIG. 2, a fluororesin substrate 1 for a high-frequency circuit has been produced by forming on a metal conductor (Cu) 12 a dielectric layer 11 using a glass cloth 11c impregnated with a fluororesin 11a.

More specifically, the material silica for forming the glass has excellent corrosion resistance against fluorine at a reflow temperature of 260° C. or higher and has a coefficient of thermal expansion lower than that of fluororesin. For this reason, when the glass cloth 11c produced by forming the above-described glass in the shape of a cloth is impregnated with the fluororesin 11a to form the dielectric layer 11, the difference in coefficient of thermal expansion between the dielectric layer 11 and the metal conductor 12 is decreased and consequently the warpage is suppressed from Occurring at the time of the reflow.

Despite the above description, a problem is caused in that the high dielectric constant, ε, of the glass cloth increases the dielectric constant, ε, of the dielectric layer 11 and consequently degrades the high-frequency characteristics.

In light of the above-described problem in the conventional technique, an object of the present invention is to offer a fluororesin substrate that sufficiently suppresses the warpage from occurring at the time of the reflow and that decreases the dielectric constant of the dielectric layer and thereby enables the exhibiting of sufficiently outstanding high-frequency characteristics.

### Solution to Problem

The present inventor has studied intensely and has found that the below-described invention can solve the above-described problem. Thus, the present invention is completed. The individual claims are explained below.

The invention stated in claim 1 is a fluororesin substrate having a metal conductor and a dielectric layer that is mainly composed of fluororesin and that is formed on the metal conductor. In the substrate, the above-described dielectric layer includes hollow glass beads.

The present inventor has studied intensely and has found that by forming a dielectric layer using fluororesin including hollow glass beads that can have a dielectric constant, ε, lower than that of a glass cloth by having a hollow structure while having corrosion resistance against fluorine and a coefficient of thermal expansion both comparable to those of the glass cloth, a fluororesin substrate can be offered that sufficiently suppresses the warpage from occurring at the time of the reflow and that decreases the dielectric constant of the dielectric layer and thereby enables the exhibiting of sufficiently outstanding high-frequency characteristics.

More specifically, because the silica forming the glass has a dielectric constant, ε, of about 3.0 and the air in the hollow portion has a dielectric constant, ε, of 1.0, by controlling the volume percentage of the hollow portion, hollow beads having a proper dielectric constant can be obtained. It is desirable that the glass beads have a dielectric constant of 1.4 to 2.8.

In addition to glass, the types of material for the hollow beads include alumina, titanium oxide, and other various materials. Among these materials, glass is most desirable in view of corrosion resistance against fluorine at the time of the reflow, pressure-withstanding property at the time of mixing with the fluororesin and of pressing to the metal conductor, stability against application of an ionizing radiation, and insulating property.

The particle diameter, size of the hollow portion, and quantity of addition to the fluororesin all of the hollow glass beads are appropriately determined in accordance with the required items such as the property and thickness of the dielectric layer and the material and thickness of the metal conductor.

The fluororesin is not particularly limited. The types of fluororesin include fluororesin such as polytetrafluoroethylene (PTFE), copolymers of two types or more of fluorine compounds such as a tetrafluoroethylene-hexafluoropropylene copolymer (FEP), and mixtures (alloys) of two types or more of fluororesin.

The term “to be mainly composed of fluororesin” means that the property of the dielectric layer is governed mainly by fluororesin and that generally, the percentage of the volume occupied by fluororesin in the dielectric layer is about 50% or more.

The types of the metal conductor to be used include copper, aluminum, iron, nickel, alloys such as SUS steel and aluminum alloy, and composites of these. Among these materials, copper and copper alloy are desirable as the metal conductor for a fluororesin substrate having a lower transmission loss because they are particularly high in conductivity. It is desirable that the thickness be 1 μm to 2 mm or so, more desirably 5 to 500 μm.

As described above, the invention stated in this claim can offer a fluororesin substrate that sufficiently suppresses the warpage from occurring at the time of the reflow and that enables the exhibiting of sufficiently outstanding high-frequency characteristics.

The invention stated in claim 2 is the fluororesin substrate as defined by claim 1 in which the above-described metal conductor has a surface roughness, Rz (JIS B 0601-1994), of 2.0 μm or less.

In a high-frequency region, as the surface roughness of the metal conductor increases, the transmission delay and transmission loss increase owing to the skin effect. In contrast, the decrease in surface roughness, Rz, of the metal conductor to 2.0 μm or less can decrease the delay and loss sufficiently, thereby enables the exhibiting of sufficiently outstanding high-frequency characteristics.

More specifically, the depth of the skin decreases as the frequency increases. For example, in the case of copper, the depth of the skin “d” is expressed as d=6.60×10⁻²/√f and therefore is inversely proportional to the square root of the frequency. For the frequency in the GHz band or higher, the control of the surface roughness Rz (a ten-data average roughness: JIS B 0601-1994) to 2.0 μm or less can sufficiently decrease the transmission delay and transmission loss.

The invention stated in claim 3 is the fluororesin substrate as defined by claim 1 or 2 in which the above-described fluororesin is irradiated with an ionizing radiation at an exposure dose of 0.01 to 500 kGy.

When an ionizing radiation such as X-rays, y-rays, and an electron beam is applied to fluororesin, fluorine radicals are produced and metal fluoride is formed at the interface with the metal conductor. This process increases affinity between the fluororesin and the metal conductor and consequently increases the intimate bondability.

It is desirable that the ionizing radiation give an exposure dose of 0.01 to 500 kGy.

The invention stated in claim 4 is the fluororesin substrate as defined by any one of claims 1 to 3 in which the above-described fluororesin is one or two or more of polytetrafluoroethylene (PTFE), a tetrafluoroethylene-perfluoroalkyl vinyl ether copolymer (PFA), a tetrafluoroethylene-hexafluoropropylene copolymer (FEP), and a tetrafluoroethylene-ethylene copolymer (ETFE).

These fluororesins are materials not only having a sufficiently low dielectric constant, ε, and dielectric tangent, tan δ, but also having excellent heat resistance. In addition, they have low moisture permeability, so that the impedance of the circuit substrate is not likely to subject to the influence of the humidity and therefore is stable.

Using such a fluororesin as the main constituent of the dielectric layer, the invention stated in this claim can offer a fluororesin substrate that is low in dielectric constant and dielectric tangent.

Among these fluororesins, PTFE is most desirable because it is the lowest both in dielectric constant and in dielectric tangent. Then, PFA and FEP are desirable in this order.

### Advantageous Effects of Invention

The present invention can offer a fluororesin substrate that sufficiently suppresses the warpage from occurring at the time of the reflow and that decreases the dielectric constant of the dielectric layer and thereby enables the exhibiting of sufficiently outstanding high-frequency characteristics.

### BRIEF DESCRIPTION OF DRAWING

FIG. 1 is a cross-sectional view schematically showing the structure of the fluororesin substrate in an embodiment of the present invention.

FIG. 2 is a cross-sectional view schematically showing an example of the structure of the conventional fluororesin substrate.

### DESCRIPTION OF EMBODIMENTS

In the following, the present invention is explained based on its embodiments and examples.

### 1. Structure of Fluororesin Substrate

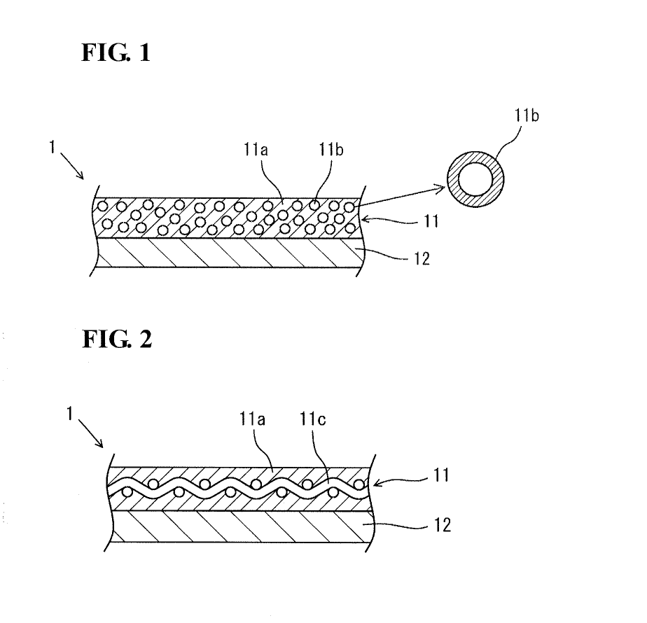

FIG. 1 is a cross-sectional view schematically showing the structure of the fluororesin substrate in this embodiment. A fluororesin substrate 1 has a metal conductor 12 and a dielectric layer 11 that is intimately bonded with the metal conductor 12. The dielectric layer 11 is composed of a fluororesin 11a and hollow beads 11b, which are made of glass.

### 2. Formation of Dielectric Layer

In the following, the formation of the dielectric layer 11 is explained.

First, a predetermined quantity of the hollow beads 11b are added to a dispersion of the fluororesin 11a such as PTFE and mixed with it.

To decrease the dielectric constant of the dielectric layer 11, it is desirable to use hollow beads having a low dielectric constant. However, hollow beads having a low dielectric constant, that is, hollow beads having a small quantity of glass (in volume ratio) have poor pressure-withstanding property. Therefore, it is desirable to use, as the hollow beads 11b, hollow beads having a dielectric constant of a value comparable to that of fluororesin, more specifically 1.4 to 2.8 or so, and having a porosity of 10% to 90% or so. The types of the above-described hollow beads include minute hollow glass spheres produced by Sumitomo 3M Limited (trade name: Glass bubbles).

The hollow beads 11b are selected so as to have a proper size by considering the thickness, strength, and so on of the dielectric layer. More specifically, it is desirable that the beads have a diameter of 0.1 to 1,000 μm. In addition, it is desirable that the beads have a specific gravity of 0.6 or so.

When the added quantity of the hollow beads 11b to the fluororesin 11a is excessively small, the occurrence of warpage of the dielectric layer 11 cannot be prevented. On the other hand, when it is excessively large, the dielectric layer 11 cannot be intimately bonded with the metal conductor 12. The quantity of addition of the hollow beads is properly determined by considering the above-described matter in addition to the required property of the dielectric layer and the dielectric constant of the hollow beads. More specifically, it is desirable to add 1 to 50 mass parts or so to 100 mass parts of fluororesin.

Next, the above-described mixture is dropped onto the metal conductor 12; uniformly applied onto the metal conductor 12 by using the spin-coating method, the casting method, or the like; and dried to form a coating.

Subsequently, the coating is pressed at a pressure of 100 MPa or so at a temperature of 350° C. Then, the coating is irradiated with an ionizing radiation such as an electron beam at 0.01 to 500 kGy in a specified low-oxygen atmosphere such as a nitrogen atmosphere. This operation firmly and intimately bonds the dielectric layer 11 with the metal conductor 12.

When the dielectric layer 11 is excessively thin, its function as a dielectric cannot be sufficiently exhibited. On the other hand, when excessively thick, its characteristic impedance becomes high. It is desirable to set the thickness at 0.5 to 200 μm, more desirably 0.5 to 50 μm, yet more desirably 5 to 30 μm.

### 3. Metal Conductor

The metal conductor 12 is explained below. The metal conductor 12 is formed by favorably using a Cu foil that has not undergone surface-roughening treatment, more specifically a Cu foil that has a smooth surface having a surface roughness, Rz (JIS B 0601-1994), of 2.0 μm or less. The use of the foregoing Cu foil decreases the transmission delay and transmission loss caused by the skin effect, as described above. In addition, it is further desirable that the metal conductor 12 do not undergo primer treatment. The conductor's thickness is set at 1 to 2,000 μm, desirably 10 to 300 μm. This thickness secures sufficient strength and enables the utilization of the skin effect by having a proper thickness.

### EXAMPLES

### 1. Production of Fluororesin Substrate

### Example 1

A fluororesin substrate was produced under the following conditions.

Dielectric Layer

Fluororesin: Produced by Daikin Industries, Ltd., Neoflon FEP (Product No.: NE-21)

Hollow beads: Produced by Sumitomo 3M Limited, Glass bubbles S60HS
True density: 0.60 g/cm³
Bulk density: 0.38 g/cm³
Pressure-withstanding strength (90% survival): 124.0 MPa
50% particle diameter: 30 μm
Glass thickness: 1.31 μm
Glass quantity (volume ratio): 24%
Dielectric constant: 2.0

Mixing ratio (mass ratio): Fluororesin : hollow beads=100:30

Thickness: 50 μm

Metal conductor: Copper foil (without primer treatment)

Thickness: 35 μm

Surface roughness (Rz): 1 μm

Lamination of dielectric layer and metal conductor

Pressing pressure: 100 MPa

Electron-beam irradiation: Exposure dose: 10 kGy
Acceleration voltage: 1,000 keV.

### Example 2

Example 2 was produced through the same method as used in Example 1, except that the following hollow beads were used.

Hollow beads: Produced by Sumitomo 3M Limited, Glass bubbles iM30K
True density: 0.60 g/cm³
Bulk density: 0.33 g/cm³
Pressure-withstanding strength (90% survival): 193.0 MPa
50% particle diameter: 16 μm
Glass thickness: 0.70 μm
Glass quantity (volume ratio): 24%
Dielectric constant: 2.0

### Comparative Example 1

Comparative example 1 was produced through the same method as used in Example 1, except that the dielectric layer was formed by using fluororesin alone without using hollow beads.

### Comparative Example 2

Comparative example 2 was produced through the same method as used in Example 1, except that the dielectric layer was formed by using the following fluororesin-impregnated glass cloth without using hollow beads.

Glass cloth: made by Chukoh Chemical Industries, Ltd. (trade name: CGN-500NF) Thickness: 1.0 mm.

2. Evaluation of Fluororesin Substrates

Produced fluororesin substrates were subjected to the examination of the dielectric constant (ε), the transmission loss in high-frequency regions (1 GHz, 10 GHz), and the status of occurrence of warpage when heated under the same condition as that at the reflow (260° C.). The status of occurrence of warpage was evaluated by the expression of “satisfactory” or “failure.”

The evaluation results for Examples 1 and 2 and Comparative examples 1 and 2 are summarized in Table I.

TABLE I

| | | | Transmission | | |
|---|---|---|---|---|---|
| | | | loss (dB/m) | | |
| | Filler | ε | 1 GHz | 10 GHz | Warpage |
| Example 1 | Hollow beads | 2.1 | 2.1 | 4.1 | Satisfactory |
| Example 2 | Hollow beads | 2.2 | 2.5 | 4.9 | Satisfactory |
| Comparative | None | 2.0 | 1.5 | 3.0 | Failure |
| example 1 | | | | | |
| Comparative | Glass cloth | 2.3 | 3.0 | 6.0 | Satisfactory |
| example 2 | | | | | |

As shown in Table I, it can be confirmed that Examples 1 and 2 have a low transmission loss and have sufficiently outstanding high-frequency characteristics in comparison with Comparative example 2, in which glass cloth was used. The reason for this is that it was possible to decrease the dielectric constant, ε, by using hollow beads in place of glass cloth. Whereas Comparative example 1, in which the dielectric layer was formed by fluororesin alone, showed the occurrence of warpage at the time of the reflow, it is confirmed that both Examples 1 and 2 can prevent the occurrence of warpage.

The above description makes clear that the present invention can offer a fluororesin substrate that eliminates the occurrence of warpage at the time of the reflow, that has a low dielectric constant, ε, and that has sufficiently outstanding high-frequency characteristics.

As described above, the present invention is explained based on its embodiments. The present invention is not limited to the embodiments described above. The above-described embodiments can be modified variously within the scope identical or equivalent to the scope of the present invention.

### Reference Signs List

1: Fluororesin substrate;
11: Dielectric layer;
11a: Fluororesin;
11b: Hollow beads;
11c: Glass cloth; and
12: Metal conductor.

1. A fluororesin substrate, comprising a metal conductor and a dielectric layer that is mainly composed of fluororesin and that is formed on the metal conductor;
the dielectric layer comprising hollow glass beads.

2. The fluororesin substrate as defined by claim 1, wherein the metal conductor has a surface roughness, Rz (JIS B 0601-1994), of 2.0 μm or less.

3. The fluororesin substrate as defined by claim 1, wherein the fluororesin is irradiated with an ionizing radiation at an exposure dose of 0.01 to 500 kGy.

4. The fluororesin substrate as defined by claim 1, wherein the fluororesin is one or two or more of polytetrafluoroethylene (PTFE), a tetrafluoroethylene-perfluoroalkyl vinyl ether copolymer (PFA), a tetrafluoroethylene-hexafluoropropylene copolymer (FEP), and a tetrafluoroethylene-ethylene copolymer (ETFE).
